(19) United States
(12) Patent Application Publication
(10) Pub. No.: US 2012/0063874 A1
(43) Pub. Date: Mar. 15, 2012

(54) LOW PROFILE DUAL ARM VACUUM ROBOT

(75) Inventor: IZYA KREMERMAN, Los Gatos, CA (US)

(73) Assignee: APPLIED MATERIALS, INC., Santa Clara, CA (US)

(21) Appl. No.: 13/232,951

(22) Filed: Sep. 14, 2011

Related U.S. Application Data
(60) Provisional application No. 61/383,140, filed on Sep. 15, 2010.

(51) Int. Cl. H01L 21/67

(52) U.S. Cl. 414/744.3

(57) ABSTRACT

Embodiments of dual arm substrate transfer robots are provided herein. In some embodiments, a dual arm substrate transfer robot may include a central actuator to rotate the transfer robot about a central axis; a linkage arm having a first end and a generally opposing second end, wherein the linkage arm is coupled to the central actuator proximate a center of the linkage arm between the first and second ends; a first forearm rotatably coupled to the first end of the linkage arm; a second forearm rotatably coupled to the second end of the linkage arm; a first forearm actuator to control the rotation of the first forearm with respect to the linkage arm; and a second forearm actuator to control the rotation of the second forearm with respect to the linkage arm, wherein the first and second forearm actuators are laterally offset from the central actuator.

### CROSS-REFERENCE TO RELATED APPLICATIONS

This Ser. No. 61/383,140, filed Sep. 15, 2010, which is herein incorporated by reference.

### FIELD

Embodiments of the present invention generally relate to apparatus for handling substrates.

### BACKGROUND

Current substrate fabrication typically requires multiple processes to be performed on a substrate in a number of different processing chambers, such as etch or deposition chambers, cool down chambers, load lock chambers, or the like. The process chambers are often part of an integrated system or cluster tool coupled to a central vacuum chamber. A transfer robot is disposed within the central vacuum chamber for moving the substrate from chamber to chamber. To increase the efficiency of the integrated system, the transfer robot is usually configured to transport multiple substrates simultaneously within the central vacuum chamber. However, as the transfer robots increase in complexity the overall size of the transfer robots also increases, eventually becoming the limiting factor in determining the compactness of the integrated system.

For example, in conventional large substrate (e.g., solar panels, carrier frame for multiple wafers, flat panel displays, or the like) fabrication processes a transfer robot may comprise a one piece construction having three or more rotational actuators stacked atop one another in a central shaft, wherein the rotational actuators control two or more arms of the transfer robot via a series of pulleys and belts. However, a transfer robot configured in such a manner possesses an overall size that makes it difficult, or impossible, to install in current integrated systems without performing substantial modifications to the integrated system. In addition, if installed, the overall size and one piece construction makes it difficult to perform maintenance on the transfer robot without completely removing it from the integrated system.

Therefore, the inventor has provided an improved substrate transfer robot for use with integrated fabrication systems.

### SUMMARY

Embodiments of dual arm substrate transfer robots are provided herein. In some embodiments, a dual arm substrate transfer robot may include a central actuator to rotate the transfer robot about a central axis; a linkage arm having a first end and a generally opposing second end, wherein the linkage arm is coupled to the central actuator proximate a center of the linkage arm between the first and second ends; a first forearm rotatably coupled to the first end of the linkage arm; a second forearm rotatably coupled to the second end of the linkage arm; a first forearm actuator to control the rotation of the first forearm with respect to the linkage arm; and a second forearm actuator to control the rotation of the second forearm with respect to the linkage arm, wherein the first and second forearm actuators are laterally offset from the central actuator.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 is a processing system suitable for use with the inventive dual arm substrate transfer robot in accordance with some embodiments of the present invention.

FIGS. 2A and 2B are cross sectional views of the inventive dual arm substrate transfer robot in accordance with some embodiments of the present invention.

FIG. 3 is a top view of the inventive dual arm substrate transfer robot in accordance with some embodiments of the present invention.

FIGS. 4A and 4B are cross sectional views of the inventive dual arm substrate transfer robot in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention generally relate to substrate transfer robots for use in integrated substrate fabrication systems. The inventive substrate transfer robot advantageously provides a common linkage arm and separate laterally offset rotational actuators to individually control the arms of the transfer robot, which provides increased control of the transfer robot while reducing the overall size of the transfer robot, thereby allowing it to be easily installed and serviced.

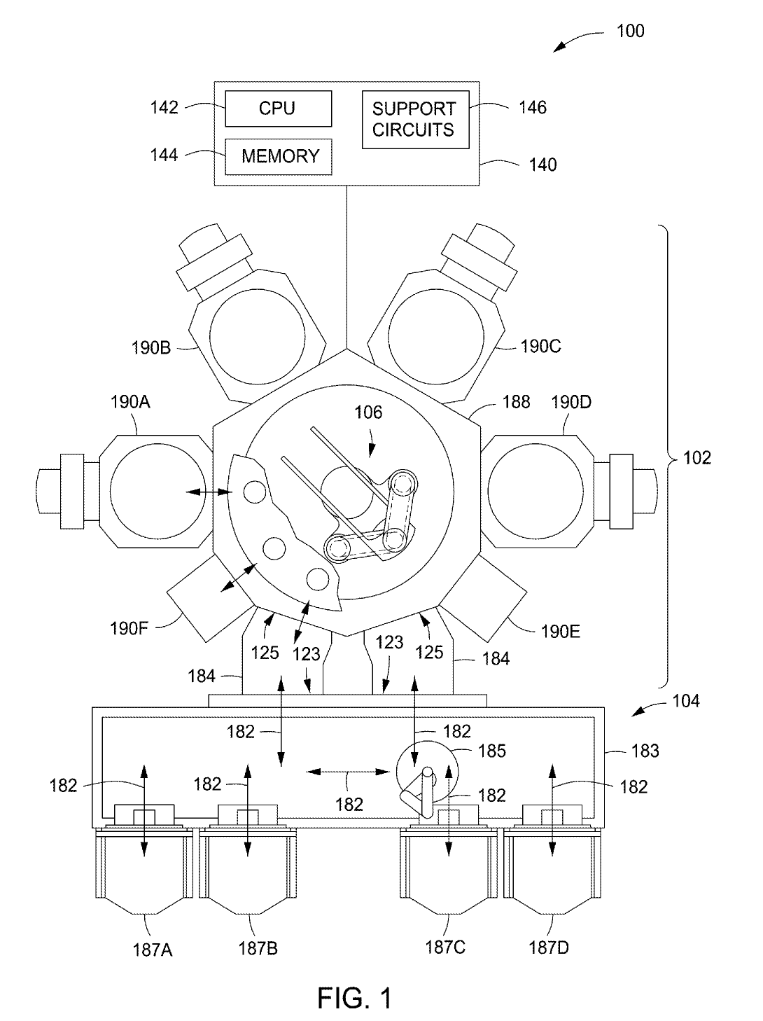

FIG. 1 is a schematic top-view diagram of an exemplary multi-chamber processing system 100 that may be suitable for use with the present inventive apparatus disclosed herein. Examples of suitable multi-chamber processing systems that may be suitably modified in accordance with the teachings provided herein include the ENDURA®, CENTURA®, and PRODUCER® processing systems (such as the PRODUCER® GT™), ADVANTEDGE™ processing systems, or other suitable processing systems commercially available from Applied Materials, Inc., located in Santa Clara, Calif. It is contemplated that other processing systems (including those from other manufacturers) may be adapted to benefit from the invention.

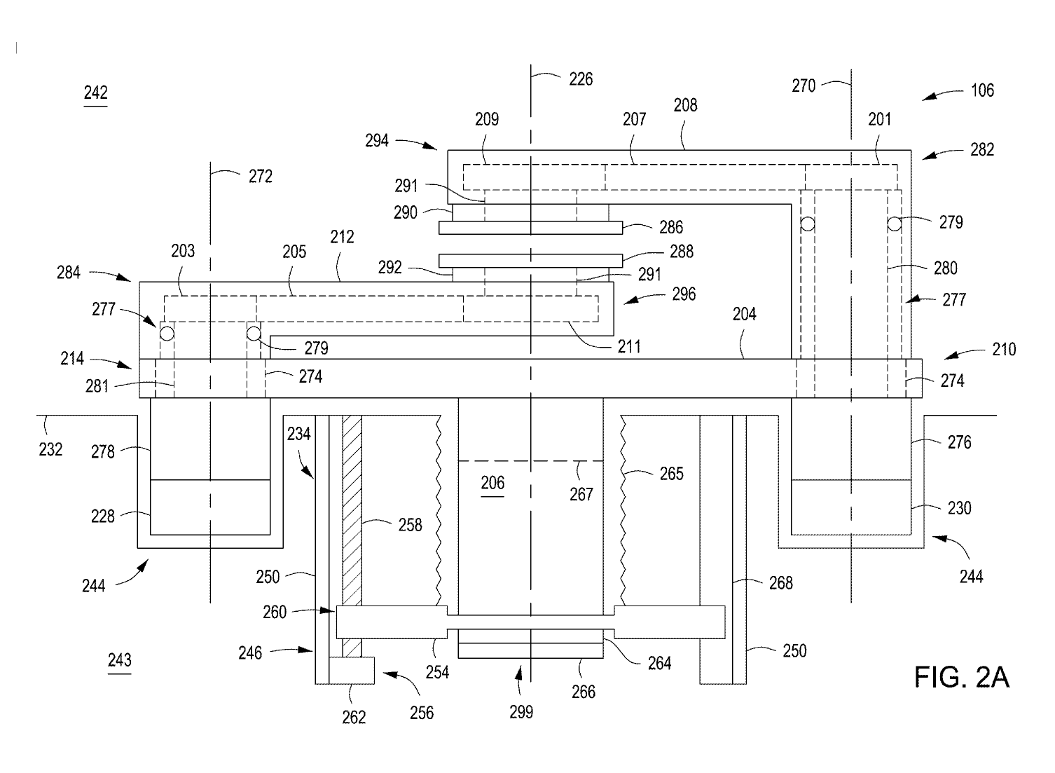

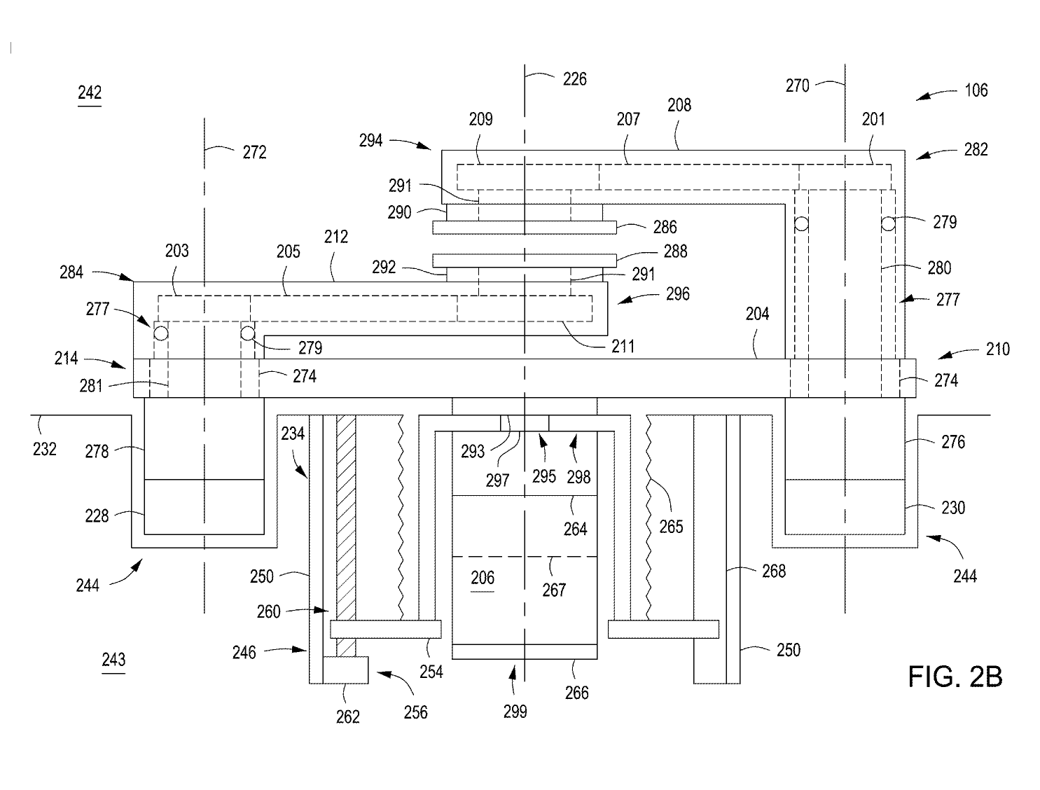

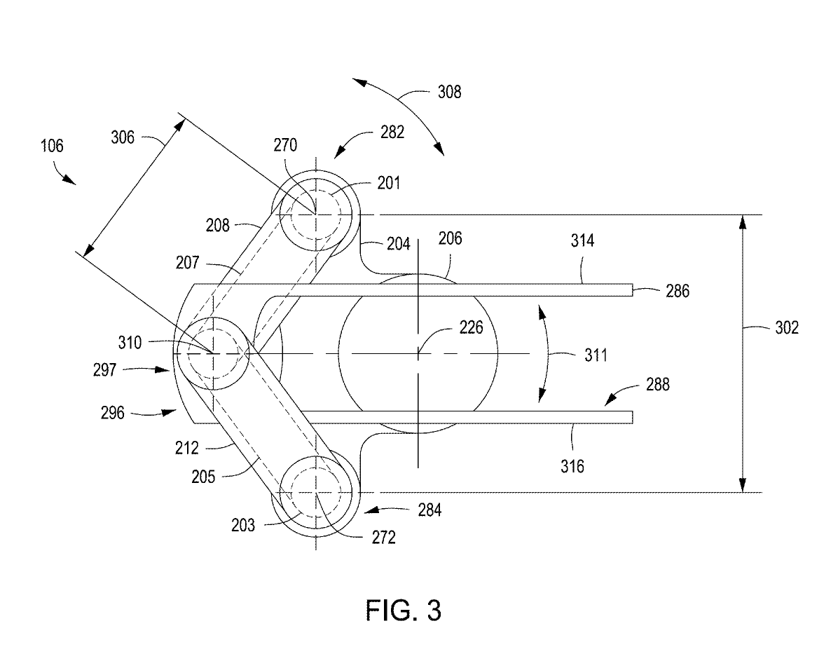

In some embodiments, a processing system 100 may generally comprise a vacuum-tight processing platform 102, a factory interface 104, and a system controller 140. The platform 102 may include a plurality of process chambers 190A-F and at least one load-lock chamber (two shown) 184 that are coupled to a transfer chamber 188. A transfer robot 106 (described below with respect to FIGS. 2 and 3) is centrally disposed in the transfer chamber 188 to transfer substrates between the load lock chambers 184 and the process chambers 190A-F. The process chambers 190A-F may be configured to perform various functions including layer deposition including atomic layer deposition (ALD), chemical vapor deposition (CVD), physical vapor deposition (PVD), etch, pre-clean, de-gas, orientation and center-finding, annealing, and other substrate processes Each of the process chambers 190A-F may include a slit valve or other selectively sealable opening to selectively fluidly couple the respective inner volumes of the process chambers 190A-F to the inner volume of the transfer chamber 188. Similarly, each load lock chamber 184 may include a port to selectively fluidly couple the respective inner volumes of the load lock chambers 184 to the inner volume of the transfer chamber 188.

The factory interface 104 is coupled to the transfer chamber 188 via the load lock chambers 184. In some embodiments, each of the load lock chambers 184 may include a first port 123 coupled to the factory interface 102 and a second port 125 coupled to the transfer chamber 188. The load lock chambers 184 may be coupled to a pressure control system which pumps down and vents the load lock chambers 184 to facilitate passing the substrate between the vacuum environment of the transfer chamber 188 and the substantially ambient (e.g., atmospheric) environment of the factory interface 104.

In some embodiments, the factory interface 104 comprises at least one docking station 183 and at least one factory interface robot (one shown) 185 to facilitate transfer of substrates from the factory interface 104 to the processing platform 102 for processing through the load lock chambers 184. The docking station 183 is configured to accept one or more (four shown) front opening unified pods (FOUPs) 187A-D. Optionally, one or more metrology stations (not shown) may be coupled to the factory interface 104 to facilitate measurement of the substrate from the FOUPs 187A-D. In some embodiments, the factory interface robot 185 disposed in the factory interface 104 is capable of linear and rotational movement (arrows 182) to shuttle cassettes of substrates between the load lock chambers 184 and a plurality of FOUPs 187A-D.

The system controller 140 controls operation of the processing system 100 using a direct control of one or more of the processing platform 102 and factory interface 104 components (i.e., the process chambers 190A-F, transfer robot 102, etc.) or alternatively, by controlling the computers (or controllers) associated with the process processing platform 102 and factory interface 104 components. In some embodiments, the system controller 140 enables data collection and feedback from the processing system 100 components to optimize performance of the processing system 100.

In some embodiments, the system controller 140 generally includes a central processing unit (CPU) 142, a memory 144, and support circuits 146. The CPU 142 may be one of any form of a general purpose computer processor that can be used in an industrial setting. The memory 144, or computer-readable medium, is accessible by the CPU 138 and may be one or more of readily available memory such as random access memory (RAM), read only memory (ROM), floppy disk, hard disk, or any other form of digital storage, local or remote. The support circuits 146 are conventionally coupled to the CPU 142 and may comprise cache, clock circuits, input/output subsystems, power supplies, and the like.

To increase substrate throughput, the transfer robot 106 is a dual arm substrate transfer robot, capable of handling two substrates simultaneously. For example, referring to FIG. 2A, in some embodiments, the transfer robot 106 generally comprises a linkage arm 204 coupled to a central actuator 206, a first forearm 208 rotatably coupled to a first end 210 of the linkage arm 204 and a second forearm 212 rotatably coupled to a second end 214 of the linkage arm 204. A first forearm actuator 230 is coupled to the first end 210 of the linkage arm 204 and is configured to control rotation of the first forearm 208 with respect to the linkage arm 204 and a second forearm actuator 228 is coupled to the second end 214 of the linkage arm 204 and is configured to control rotation of the second forearm 212 with respect to the linkage arm 204.

The central actuator 206 supports the linkage arm 204 and facilitates rotational movement of the linkage arm 204 about a central axis 226. The central actuator 206 may be any rotational actuator capable of providing the aforementioned rotational movement, for example such as a mechanical motor, such as a hydraulic motor, pneumatic motor, or the like, or an electrical motor, such as a servo motor, stepper motor, or the like. In some embodiments, the central actuator 206 and linkage arm 204 may be coupled to a mechanical gear system 267 such as a gear box or strain wave gear system to facilitate precise movement and provide an adjustable gear ratio to facilitate efficient transfer of energy from the central actuator 206 to the linkage arm 204. In embodiments where the central actuator 206 is an electrical motor, an electrical feedthrough 264 and/or slip ring 266 may be coupled to the central actuator 206 to facilitate the flow of power from a power source (not shown) to the central actuator 206.

In some embodiments, the central actuator 206 may be coupled to a lift 246 to facilitate vertical movement of the transfer robot 106. In some embodiments, the lift 246 may generally comprise a lift actuator 256 coupled to a housing 250 and configured to provide vertical movement of the central actuator 206. In some embodiments, a bellows 265 is coupled to the housing 250 and lift actuator 256 to provide a vacuum seal to facilitate maintaining a desired atmosphere (e.g., vacuum conditions) within the inner volume 242 of the transfer chamber 188. The lift actuator 256 may comprise any actuator suitable to provide the vertical motion of the central actuator 206. For example, in some embodiments, the lift actuator 256 may comprise a rotational actuator 262 coupled to a threaded shaft 258 of a ball screw 260. In such embodiments, the ball screw 260 may be coupled to the central actuator 206 via a carriage 254. In some embodiments, the carriage 254 may be movably coupled to one or more (one shown) guide rails 268 to facilitate smooth and precise movement of the carriage 254. In operation, the rotational actuator 262 rotates the threaded shaft 258 causing vertical movement of the ball screw 260 and thus, vertical movement of the carriage 254, thereby facilitating movement of the central actuator 206.

Although FIG. 2A depicts the carriage 254 coupled to the central actuator 206 proximate the bottom 299 of the central actuator 206, the carriage 254 may be coupled to central actuator 206 at any position. For example, in some embodiments, such as depicted in FIG. 2B, the carriage 254 may be coupled to the central actuator 206 proximate the top 298 of the central actuator 206. In such embodiments the central actuator 206 may be coupled to the linkage arm 204 via a shaft 297 disposed within a through hole 295 of the carriage 254. In some embodiments, the shaft 297 may be coupled to the linkage arm 204 via a plate 293.

By coupling the carriage 254 to the central actuator 206 proximate the top 298 of the central actuator 206 a separation between the inner volume 242 that is maintained at a desired atmosphere (such as a vacuum atmosphere) and an outer volume 243 that is not maintained at the desired atmosphere is located above the central actuator 206, thereby allowing for the central actuator 206 to be serviced without having to access the inner volume 242 of the transfer chamber 188.

Returning to FIG. 2A, the transfer robot 106 may be coupled to the inner volume 242 of the transfer chamber 188 via any manner suitable to provide sufficient stability to allow the transfer robot 106 to facilitate substrate movement. In some embodiments, a bottom surface 232 of the transfer chamber 188 may comprise one or more recesses (i.e., first recess 234 and second recess 244) configured to accommodate the size and movement of the central actuator 206, first forearm actuator 230 and second forearm actuator 228. For example, in such embodiments, the second recess 234 may provide a circular path to allow the first forearm actuator 230 and second forearm actuator 228 to travel through the second recess 234 as the central actuator 206 rotates the transfer robot 106 about a central axis 226 of the transfer chamber 188. When present, the one or more recesses reduce the size of the inner volume 242 necessary to accommodate the overall height of the transfer robot 106. Reducing the size of the inner volume 242 of the transfer chamber 188 provides a smaller volume that needs to be evacuated to obtain a desired atmosphere (e.g., vacuum conditions). Moreover, in existing equipment having small available physical space available, the low height of the transfer robot facilitates incorporation of the transfer robot 106 into suitably modified existing equipment.

In some embodiments, the first forearm actuator 230 and second forearm actuator 228 are coupled to opposing ends of the linkage arm 204 (i.e., the first end 210 and second end 214, respectively) and are positioned laterally offset from the central actuator 206. Providing the central actuator 206, first forearm actuator 230 and second forearm actuator 228 in a laterally offset configuration eliminates the need for having multiple actuators stacked on top of one another beneath the linkage arm 204, thereby reducing the overall height of the transfer robot 106. In addition, laterally offsetting the central actuator 206, first forearm actuator 230 and second forearm actuator 228 allows for each actuator to be individually accessed, thereby eliminating the need to remove the entire transfer robot 106 for maintenance or repair. In addition, in some embodiments, the central actuator 206, the first forearm actuator 230, and the second forearm actuator 228, need not be in linear alignment, for example as depicted in FIG. 3.

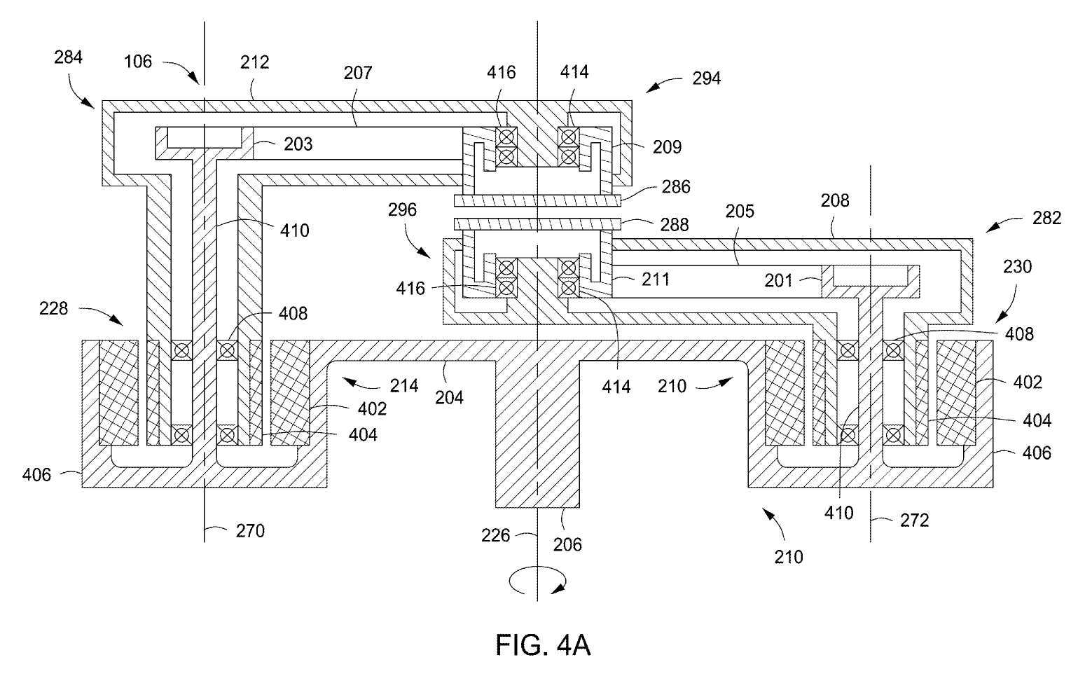

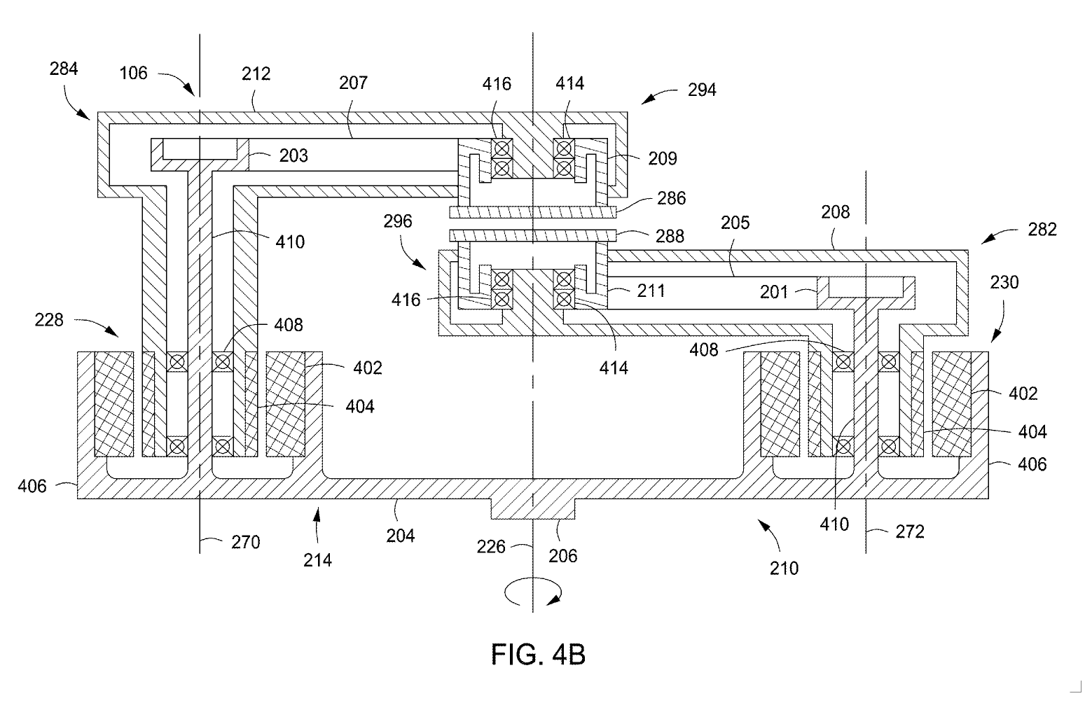

Returning to FIG. 2A, the first forearm actuator 230 and second forearm actuator 228 may be coupled to the linkage arm 204 in any manner suitable to provide a secure, static coupling. In some embodiments, as depicted in FIGS. 2A and 4A, the first forearm actuator 230 and second forearm actuator 228 may be coupled to the linkage arm 204 such that the actuators are disposed generally below the linkage arm 204. In some embodiments, for example as depicted in FIG. 4B, the first forearm actuator 230 and second forearm actuator 228 may be coupled to the linkage arm 204 such that the actuators are disposed generally above the linkage arm 204.

In some embodiments, the first end 210 and second end 214 of the linkage arm 204 may each include a through hole 274 sized to accommodate at least a portion of the respective first forearm actuator 230 and second forearm actuator 228. In such embodiments, a shaft 280, 281 may extend through the respective through holes 274 to facilitate coupling of the first forearm actuator 230 and second forearm actuator 228 to the first forearm 208 and second forearm 212, thereby allowing the first forearm actuator 230 and second forearm actuator 228 to respectively control rotation of the first forearm 208 and second forearm 212. In some embodiments, one or more ball bearings (one ball bearing 279 for each of the first forearm 208 and second forearm 212 shown) may be disposed within a gap 277 between the first forearm 208 and second forearm 212 and the respective shaft 280, 281 to provide smooth rotational movement.

Each of the first forearm actuator 230 and second forearm actuator 228 may be any type of rotational actuator capable of providing rotational movement of the first forearm 208 and second forearm 212 about a respective first forearm axis 270 and second forearm axis 272. For example, the first forearm actuator 230 and second forearm actuator 228 may be any of the rotational actuators discussed above with respect to the central actuator 206. In some embodiments, the first forearm actuator 230 and second forearm actuator 228 may be the same, or in some embodiments, a different type of actuator as the central actuator 206. In some embodiments, the first forearm actuator 230 and second forearm actuator 228 may be coupled to a mechanical gear system 276, 278 such as a gear box or strain wave gear system to facilitate precise movement and provide an adjustable gear ratio to facilitate an efficient transfer of energy from the first forearm actuator 230 and second forearm actuator 228 to the first forearm 208 and second forearm 212, respectively. In addition, in some embodiments, the first forearm actuator 230 and second forearm actuator 228 may further comprise an electromechanical device (not shown) to facilitate precise rotation, for example, an encoder, such as a rotary encoder or shaft encoder.

In some embodiments, each of the first end 210 and the second end 214 of the linkage arm 204 may comprise a housing 406 configured to house components first forearm actuator 230 and second forearm actuator 228, for example, as shown in FIGS. 4A and 4B. For example, in such embodiments, the first forearm actuator 230 and second forearm actuator 228 may each comprise a stator 402 coupled to the housing 406 and configured to control rotation of a rotor 404 coupled to each of the first forearm 208 and second forearm 212. Ball bearings 408 may be disposed between the rotor 404 and a shaft 410 statically coupled to the housing 406 to provide smooth rotational movement. Although the housing 406 and linkage arm 204 are shown in the figure as one integral part, the housing 406 may be a separate component configured to be coupled to the linkage arm 204.

Referring back to FIG. 2A, in some embodiments, each of the first forearm 208 and second forearm 212 are rotatably coupled to the linkage arm 204 at a first end 282, 284. An end effector is (286, 288) is rotatably coupled to each of the first forearm 208 and second forearm 212 proximate a second end 294, 296 of the forearms 208, 212 opposite the first end 282, 284. In some embodiments, each end effector 286, 288 is coupled to the first forearm 208 and second forearm 212 via an end effector mounting surface 290, 292. When present, the end effector mounting surface 290, 292 provides spacing between the first forearm 208 and second forearm 212 and respective end effector 286, 288.

In some embodiments, a first pulley 201, 203 is coupled to each of the first end 282 of the first forearm 208 and the first end 284 of the second forearm 212. In some embodiments, the first pulley 201, 203 is statically coupled to the shaft 410, for example, as shown in FIGS. 4A and 4B.

Referring back to FIG. 2A, the first pulleys 201, 203 are coupled to respective second pulleys 209, 211 disposed proximate the second ends 294, 296 of the first forearm 208 and second forearm 212 via respective belts 205, 207. The second pulleys 209, 211 are rotatably coupled to the second ends 294, 296 of the first forearm 208 and second forearm 212 and fixed to the end effectors 286, 288 via a shaft 291. In some embodiments, the second pulleys 209, 211 may be rotatably coupled to the first forearm 208 and second forearm 212 via a shaft 416 disposed within the second ends 294, 296 of the first forearm 208 and second forearm 212, for example, as shown in FIGS. 4A and 4B. In such embodiments, bearings 414 may be disposed between the second pulleys 209, 211 and shaft 416 to provide smooth rotational movement.

Referring to FIGS. 4A and 4B, in operation, the first forearm actuator 230 and/or second forearm actuator 228 rotates the first forearm 208 and/or second forearm 212 about the shaft 410 and about the respective first pulley 201, 203, which remains in a static rotational position relative to the linkage arm 204. The rotation of the first forearm 208 and/or second forearm 212 causes rotation of the second pulley 209, 211 via the belt 205, 207, thereby rotating the end effector 286, 288 with respect to the first forearm 208 and second forearm 212.

In some embodiments, a ratio of the size of the first pulley 201, 203 with respect to the second pulley 209, 211 may be selected to facilitate controlling the rate of rotation and rotational displacement of the second pulley 209, 211, and the end effector 286, 288 when rotated by the first pulley 201, 203. For example, in some embodiments, when the center-to-center distance between the first pulley 201, 203 and the second pulley 209 is equal to the center-to-center distance between the first pulley 201, 203 and the central axis 226, a ratio of the size of the first pulley 201, 203 to second pulley 209, 211 may be about 1:2. Such a ratio maintains the orientation of the end effector with respect to the transfer robot 106 during actuation of the first forearm 208 and/or second forearm 212. Other size ratios may be used with different center-to-center distances as discussed above.

The end effector 286, 288 may be configured in any manner suitable to provide adequate support to a substrate disposed thereon. For example, in some embodiments, the end effector 286, 288 may comprise a one or more support arms (two shown) 314, 316, as shown in FIG. 3.

In operation, coordination of the actuators (i.e., central actuator 206, first forearm actuator 230 and second forearm actuator 228) may provide movement of the transfer robot 106 in any direction required to provide a desired movement of substrates. For example, in some embodiments, the central actuator 206 may be rotated in a first direction 310, for example clockwise, and the first forearm actuator 230 (or second forearm actuator 228) may be rotated in an opposite direction 308, for example counter clockwise, thereby causing the first forearm 208 (or second forearm 212) and end effector 286 to move in a forward direction.

In some embodiments, the lengths of each of the first forearm 208 and second forearm 212 (as measured from the first forearm axis 270 or the second forearm axis 272 to the end effector 286, 288 axis of rotation 310) with respect to the length 302 of the linkage arm 204 (as measured from first forearm axis 270 to the second forearm axis 272) may be varied to adjust the rotational displacement of the first forearm 208 and second forearm 212 with respect to the linkage arm 204. In such embodiments, the lengths of each of the first forearm 208 and second forearm 212 with respect to the length 302 of the linkage arm 204 may dictate a rotational displacement of the central actuator 206 with respect to a rotational displacement of the first forearm actuator 230 (or second forearm actuator 228) necessary to move the end effector 286, 288 in a desired direction.

For example, in embodiments where the central actuator 206 may be rotated in a first direction 310 and the first forearm actuator 230 may be rotated in an opposite direction 308 to move the end effector 286 in a forward direction as described above, if the length 306 of the first forearm 208 is approximately one half (½) the length 302 of the linkage arm 204, the rotational displacement a of the first forearm actuator 230 may be approximately twice (2α) the rotational displacement of the central actuator 206. Alternatively, in embodiments where the length 306 of the first forearm 208 is greater than, or less than, one half (½) the length 302 of the linkage arm 204 the rotational displacement of the first forearm actuator 230 may be varied to be greater than, or less than, approximately twice the rotational displacement of the central actuator 206 to achieve movement of the end effector 286, 288 in the desired direction.

Thus, an improved substrate transfer robot for use with integrated fabrication systems has been provided herein. The inventive substrate transfer robot advantageously provides a common linkage arm and separate laterally offset rotational actuators to individually control the arms of the transfer robot, which provides increased control of the transfer robot while reducing the overall size of the transfer robot, thereby allowing it to be easily installed and serviced.

While the foregoing is directed to embodiments of the present invention, other and further embodiments of the invention may be devised without departing from the basic scope thereof.

1. A dual arm substrate transfer robot, comprising:
a central actuator to rotate the transfer robot about a central axis;
a linkage arm having a first end and a generally opposing second end, wherein the linkage arm is coupled to the central actuator proximate a center of the linkage arm between the first and second ends;
a first forearm rotatably coupled to the first end of the linkage arm;
a second forearm rotatably coupled to the second end of the linkage arm;
a first forearm actuator to control the rotation of the first forearm with respect to the linkage arm; and
a second forearm actuator to control the rotation of the second forearm with respect to the linkage arm, wherein the first and second forearm actuators are laterally offset from the central actuator.

2. The substrate transfer robot of claim 1, further comprising:
a first end effector rotatably coupled to a first end of the first forearm and a second end effector rotatably coupled to a first end of the second forearm, each end effector configured to support a substrate thereon.

3. The substrate transfer robot of claim 2, wherein each of the first and second forearms further comprise:
a first pulley coupled to the end effector and rotatably coupled to the first end of each of the first forearm and the second forearm;
a second pulley coupled to a second end of the first forearm and second forearm, opposite the first end and statically coupled to the linkage arm; and
a belt coupling the first pulley to the second pulley such that actuation of the first forearm actuator or the second forearm actuator causes respective rotation of the first end effector and the second end effector with respect to the first forearm or second forearm.

4. The substrate transfer robot of claim 3, wherein a center-to-center distance between the first pulley and the second pulley is equal to the center-to-center distance between the first pulley and the central axis, and wherein the first pulley and the second pulley comprise a size ratio of the first pulley to the second pulley of about 1:2.

5. The substrate transfer robot of claim 1, wherein the substrate transfer robot is disposed within a transfer chamber of a substrate processing system.

6. The substrate transfer robot of claim 5, wherein the transfer chamber comprises:
a bottom surface for coupling the substrate transfer robot to the transfer chamber, wherein the bottom surface comprises a plurality of recesses to allow the first forearm actuator, the second forearm actuator, and the central actuator to rotate therein.

7. The substrate transfer robot of claim 1, further comprising:
a lift coupled to the central actuator to control vertical movement thereof.

8. The substrate transfer robot of claim 7, wherein the lift comprises:
a lift actuator; and
a carriage coupling the lift actuator to the central actuator, wherein the lift actuator controls vertical movement of the carriage.

9. The substrate transfer robot of claim 1, wherein the central actuator, the first forearm actuator, and the second forearm actuator are a rotational hydraulic pump, an electric motor, a hydraulic motor, or a pneumatic motor.

10. The substrate transfer robot of claim 1, further comprising:
a first gear box rotatably coupling the first forearm to the first forearm actuator to transfer rotational energy from the first forearm actuator to the forearm; and
a second gear box rotatably coupling the second forearm to the second forearm actuator to transfer rotational energy from the second forearm actuator to the second forearm.

11. The substrate transfer robot of claim 10, wherein the first gear box and second gear box each comprise a strain wave gear system drive.

12. The substrate transfer robot of claim 1, wherein rotational axes of the first forearm actuator, the second forearm actuator, and the central axis are coplanar.

13. The substrate transfer robot of claim 1, wherein rotational axes of the first forearm actuator and the second forearm actuator are coplanar with respect to each other and are offset with respect to the central axis.

14. The substrate transfer robot of claim 1, wherein each of the first forearm and the second forearm comprise a length substantially equal to one half a length of the linkage arm.

15. The substrate transfer robot of claim 1, wherein each of the first forearm and the second forearm comprise a length greater than one half a length of the linkage arm.

16. The substrate transfer robot of claim 1, wherein each of the first and second forearm actuators are disposed predominantly below the linkage arm.

17. The substrate transfer robot of claim 1, wherein each of the first and second forearm actuators are disposed predominantly above the linkage arm.

18. A dual arm substrate transfer robot, comprising:
a central actuator to rotate the transfer robot about a central axis;
a linkage arm having a first end and a generally opposing second end, wherein the linkage arm is coupled to the central actuator proximate a center of the linkage arm between the first and second ends;
a first forearm rotatably coupled to the first end of the linkage arm;
a second forearm rotatably coupled to the second end of the linkage arm;
a first forearm actuator to control the rotation of the first forearm with respect to the linkage arm, the first forearm actuator disposed along an axis of rotation of the first forearm; and
a second forearm actuator to control the rotation of the second forearm with respect to the linkage arm, the second forearm actuator disposed along an axis of rotation of the second forearm.

19. The substrate transfer robot of claim 1, further comprising:
a lift coupled to the central actuator to control vertical movement thereof.

20. The substrate transfer robot of claim 18, wherein the central actuator, the first forearm actuator, and the second forearm actuator are a rotational hydraulic pump, an electric motor, a hydraulic motor, or a pneumatic motor.
